(19) United States
(12) Patent Application Publication
(10) Pub. No.: US 2015/0331058 A1
(43) Pub. Date: Nov. 19, 2015

(54) VOLTAGE DETECTING DEVICE

(71) Applicant: Keihin Corporation, Tokyo (JP)

(72) Inventor: Seiji Kamata, Shioya-gun (JP)

(73) Assignee: KEIHIN CORPORATION, Tokyo (JP)

(21) Appl. No.: 14/701,907

(22) Filed: May 1, 2015

(30) Foreign Application Priority Data
May 15, 2014 (JP) 2014-101331

(51) Int. Cl. G01R 31/36

(52) U.S. Cl. CPC G01R 31/3658; G01R 31/362

(57) ABSTRACT

Disclosed herein is a voltage detecting device including: a voltage detecting circuit that is provided for each of a plurality of battery cell groups configuring a battery and detects a voltage of the battery cell group; a control circuit that is insulated from the voltage detecting circuit and controls the battery on the basis of the voltage; a control circuit board equipped with the control circuit; a first communicating element mounted on the control circuit board; a voltage detecting circuit board that is equipped with the voltage detecting circuit and is disposed in parallel to the control circuit board; and a second communicating element that is mounted on the voltage detecting circuit board and is capable of contactless communication with the first communicating element; the first communicating element and the second communicating element being disposed opposed to each other.

### CROSS REFERENCE TO RELATED APPLICATION

The present claims priority under 35 U.S.C. §119 to Japanese Patent Application No 2014-101331 filed in the Japan Patent Office on May 15, 2014, the entire content of which is hereby incorporated by reference.

### TECHNICAL FIELD

The present invention relates to a voltage detecting device.

### BACKGROUND OF THE INVENTION

Japanese Patent Laid-open No. Hei 9-23009 discloses a communicating device that is suitable for information communications of a measuring device attached to a battery mounted in an automobile or the like and does not need connecting by a connector. This communicating device has a measuring device that measures information on the voltage, temperature, pressure, and so forth of the battery and a control device that controls the battery on the basis of the information measured by the measuring device.

The measuring device and the control device are connected to each other via a pair of communicating elements, and the pair of communicating elements are capable of transmitting a signal by using wireless communications through placement of the battery on a battery housing base.

### SUMMARY OF THE INVENTION

In the above-described patent document, although a structure in which connecting by a connector is eliminated by using wireless communications, the control device and the measuring device are connected with the intermediary of the battery housing base. This causes a problem that increase in the number of measuring devices leads to increase in the size of the device.

The present disclosure is made in view of such circumstances and it is desirable to achieve size reduction of a voltage detecting device that detects the voltage of a battery.

According to an embodiment of the present disclosure, there is provided a voltage detecting device including a voltage detecting circuit that is provided for each of a plurality of battery cell groups configuring a battery and detects the voltage of the battery cell group and a control circuit that is insulated from the voltage detecting circuit and controls the battery on the basis of the voltage. The voltage detecting device further includes a control circuit board equipped with the control circuit, a first communicating element mounted on the control circuit board, a voltage detecting circuit board that is equipped with the voltage detecting circuit and is disposed in parallel to the control circuit board, and a second communicating element that is mounted on the voltage detecting circuit board and is capable of contactless communication with the first communicating element. The first communicating element and the second communicating element are disposed opposed to each other.

The voltage detecting device may further include a discharge element that is mounted on the voltage detecting circuit board and discharges the battery cell group in an overcharged state and an insulating resin plate disposed between the control circuit board and the voltage detecting circuit board.

Alternatively, the voltage detecting device may further include a discharge element that is mounted on the voltage detecting circuit board and discharges the battery cell group in an overcharged state and a metal cover that is in contact with the discharge element and covers at least part of the voltage detecting circuit board.

According to the embodiment of the present disclosure, the control circuit board and the voltage detecting circuit board are disposed in parallel, with the first communicating element and the second communicating element set opposed to each other. This can reduce the size of the voltage detecting device.

### BRIEF DESCRIPTION OF THE DRAWINGS

The advantages of this invention will become apparent in the following description taken in conjunction with the drawings, wherein:

FIG. 1 is a perspective view of a battery and a voltage detecting device according to a first embodiment of the present disclosure;

FIG. 2A is a sectional view of the voltage detecting device according to the first embodiment of the present disclosure and FIG. 2B is an enlarged view of a part A shown in FIG. 2A;

FIG. 3 is a circuit diagram of the voltage detecting device according to the first embodiment of the present disclosure; and

FIG. 4 is a sectional view of a voltage detecting device according to a second embodiment of the present disclosure.

### DETAILED DESCRIPTION OF THE INVENTION

Embodiments of the present disclosure will be described below with reference to the drawings.

### First Embodiment

A voltage detecting device according to a first embodiment of the present disclosure is mounted in a moving vehicle having a battery, such as an electric vehicle (EV) or a hybrid vehicle (HV). The battery is e.g. a secondary battery (rechargeable battery) such as a lithium ion secondary battery and is disposed at the bottom part of the moving vehicle as a battery pack having a rectangular parallelepiped shape.

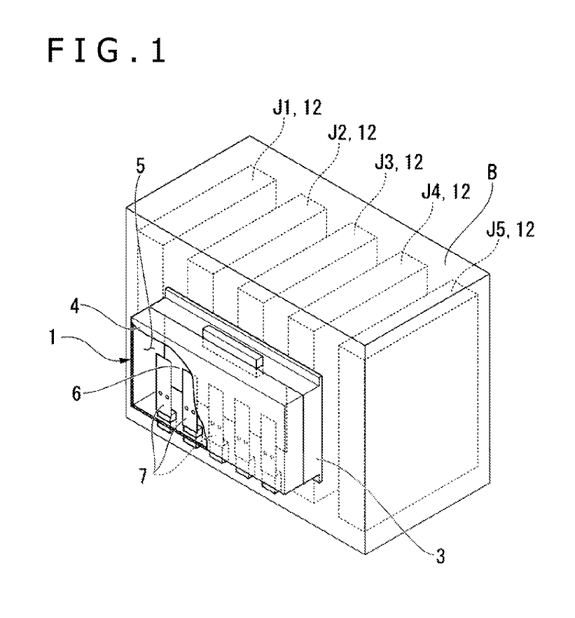

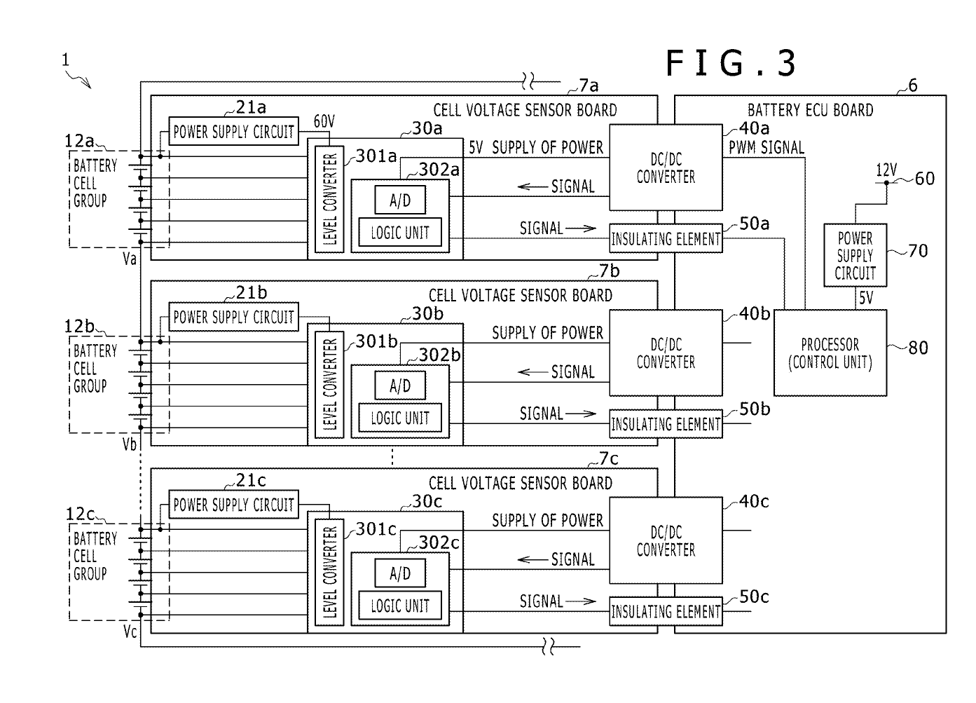

As shown in FIG. 1, a voltage detecting device 1 is fixed to a side surface of a battery B. The battery B includes plural (five, in the present embodiment) battery modules J1 to J5 and each of the battery modules J1 to J5 has plural battery cells (battery cell group 12, see FIG. 3). The voltage detecting device 1 monitors the voltage state of the battery cell groups 12.

The voltage detecting device 1 includes: a resin case 3 fixed to the side surface of the battery B; a metal cover 4 that is used in combination with the resin case 3 and forms a board housing space 5 between the metal cover 4 and the resin case 3; and a battery electronic control unit (ECU) board 6 and plural cell voltage sensor boards 7 that are housed in the board housing space 5.

The battery ECU board 6 is equipped with a processor 80 (see FIG. 3, control circuit) configured to control the battery B. The cell voltage sensor board 7 is equipped with an integrated circuit 30 (voltage detecting circuit, see FIG. 3) having functions to measure at least the cell voltage of the battery cell group 12 and transmit information on the cell voltage to the battery ECU board 6.

The voltage detecting device 1 is obtained by housing the battery ECU board 6 and the plural cell voltage sensor boards 7 inside the casing formed of the resin case 3 and the metal cover 4 and integrating these components into a package as one unit. The integrated circuit 30 is electrically insulated from the processor 80 and is communicably connected to the processor 80.

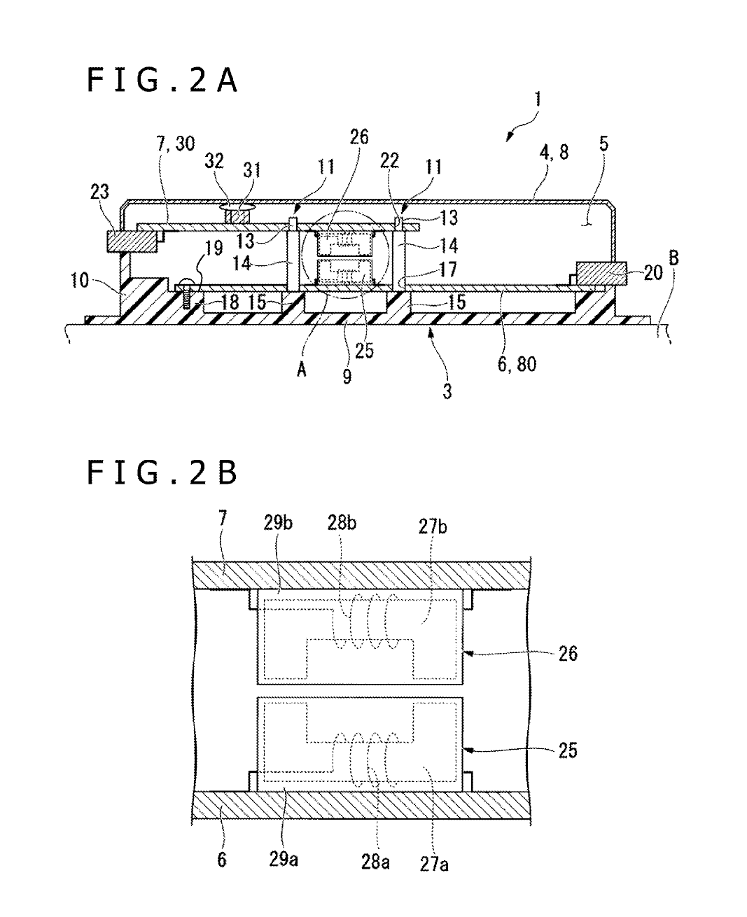

The resin case 3 is a tray-shaped case on which the battery ECU board 6 and the cell voltage sensor boards 7 can be placed and is fixed to the side surface of the battery B by using fastening measures such as bolts. As shown in FIG. 2A, the resin case 3 has a base part 9 and a wall part 10 protruding from the edge part of the base part 9.

The base part 9 of the resin case 3 has a rectangular plate shape having an outer shape slightly larger than the battery ECU board 6. Furthermore, on the base part 9 of the resin case 3, plural locating pins 11 protruding in the same direction as the protrusion direction of the wall part 10 and toward the opposite side to the battery B are formed.

The locating pins 11 settle the positions of the battery ECU board 6 and the cell voltage sensor boards 7 in such a manner that the battery ECU board 6 is disposed in parallel to the cell voltage sensor boards 7 when the battery ECU board 6 and the cell voltage sensor boards 7 are housed in the resin case 3. By being located by the locating pins 11, the battery ECU board 6 and the cell voltage sensor boards 7 are so disposed that, as shown in FIG. 1, the plural cell voltage sensor boards 7 disposed in parallel at a predetermined interval from the battery ECU board 6 are lined up in the longitudinal direction of the battery ECU board 6.

At least two locating pins 11 are formed per one cell voltage sensor board 7 and all locating pins 11 penetrate the battery ECU board 6.

Each locating pin 11 has a circular pillar shape and is so formed that the diameter decreases in a stepwise manner from the base end part to the tip part. Specifically, the locating pins 11 each have a locating pin first portion 13 closest to the tip side, a locating pin third portion 15 closest to the base end side, and a locating pin second portion 14 between the locating pin first portion 13 and the locating pin third portion 15. The diameter of the locating pin second portions 14 is set larger than that of the locating pin first portions 13. The diameter of the locating pin third portions 15 is set larger than that of the locating pin second portions 14.

In the battery ECU board 6, plural locating holes 17 corresponding to the locating pins 11 are formed. That is, when the battery ECU board 6 is attached to the resin case 3, the position of the battery ECU board 6 is settled by insertion of the locating pins 11 into the locating holes 17 of the battery ECU board 6. The locating holes 17 of the battery ECU board 6 have a diameter that is slightly larger than that of the locating pin second portions 14 of the locating pins 11 and is smaller than that of the locating pin third portions 15.

The locating pin third portions 15 are so formed that the battery ECU board 6 is supported at such a height as to be disposed in parallel to the base part 9 of the resin case 3.

In the wall part 10 of the resin case 3, a first support part 18 having a first support surface 19 to support the battery ECU board 6 is formed. The first support part 18 is so formed that the height of the first support surface 19 from the base part 9 is substantially the same as that of the upper ends of the locating pin third portions 15 from the base part 9.

The battery ECU board 6 is provided with a connector 20 and the connector 20 is so attached as to be exposed to the outside of the board housing space 5 when the metal cover 4 is attached to the resin case 3.

The cell voltage sensor board 7 is formed with a smaller size than the battery ECU board 6. For example, the cell voltage sensor board 7 is about one-fifth of the size of the battery ECU board 6 and the plural cell voltage sensor boards 7 can be housed in the board housing space 5 in such a manner as to be lined up in the longitudinal direction of the battery ECU board 6.

In the cell voltage sensor boards 7, plural locating holes 22 corresponding to the locating pins 11 are formed. The locating holes 22 of the cell voltage sensor boards 7 have a diameter that is slightly larger than that of the locating pin first portions 13 and is smaller than that of the locating pin second portions 14.

The locating pin third portions 15 are so formed that the battery ECU board 6 is supported at such a height as to be disposed in parallel to the base part 9 of the resin case 3.

The locating pin second portions 14 are so formed that the cell voltage sensor board 7 is supported at such a height as to be disposed in parallel to the base part 9 of the resin case 3 and the battery ECU board 6. In other words, due to the supporting of the battery ECU board 6 by the locating pin third portions 15 and the supporting of the cell voltage sensor board 7 by the locating pin second portions 14, the battery ECU board 6 and the cell voltage sensor board 7 are disposed at a predetermined interval, with their major surfaces parallel to each other.

The cell voltage sensor board 7 is provided with a connector 23 and the connector 23 is so attached as to be exposed to the outside of the board housing space 5 when the metal cover 4 is attached to the resin case 3.

The metal cover 4 has such a shape as to cover the battery ECU board 6 and the cell voltage sensor boards 7 except for the connectors 20 and 23 in cooperation with the resin case 3. The metal cover 4 has a cover surface 8 that is a major surface parallel to the base part 9 of the resin case 3.

Communicating elements 25 and 26 capable of wireless communications with each other are mounted on the battery ECU board 6 and the cell voltage sensor board 7.

The first communicating element 25 is mounted on the battery ECU board 6 and on its surface opposed to the cell voltage sensor board 7. The second communicating element 26 configured to transmit the cell voltage is mounted on the cell voltage sensor board 7 and on its surface opposed to the battery ECU board 6.

The first communicating element 25 and the second communicating element 26 are disposed opposed to each other across a distance allowing wireless communications with each other. Specifically, the first communicating element 25 and the second communicating element 26 are disposed at substantially the same position when being viewed from the direction orthogonal to the major surfaces of the battery ECU board 6 and the cell voltage sensor board 7 disposed in parallel to each other.

As shown in FIG. 2B, the first communicating element 25 has a core 27a of a magnetic material, a coil 28a wound around the core 27a, and an insulating resin 29a covering the core 27a and the coil 28a. The second communicating element 26 has a core 27b of a magnetic material, a coil 28b wound around the core 27b, and an insulating resin 29b covering the core 27b and the coil 28b. Both ends of the coil 28b of the second communicating element 26 mounted on the cell voltage sensor board 7 are connected to the integrated circuit 30. The coil 28a of the first communicating element 25 mounted on the battery ECU board 6 is connected to the processor 80.

The coil 28a is a primary coil. Furthermore, the coil 28b is a secondary coil. The coil 28a and the coil 28b are so disposed as to have polarities opposite to each other and form a pulse transformer.

As shown in FIG. 2A, a discharge resistor 31 is mounted on the cell voltage sensor board 7 and on its surface on the opposite side to the surface facing the battery ECU board 6. One end of the discharge resistor 31 is connected to the positive electrode of the battery cell group 12 and the other end of the discharge resistor 31 is connected to the ground via a switching element provided inside the integrated circuit 30.

When the battery cell group 12 becomes overcharged, the discharge resistor 31 turns the switching element to the on-state. The discharge resistor 31 is thereby supplied with power from the battery cells in the overcharged state and converts the power to thermal energy to generate heat.

A thermal coupling agent such as a thermal grease 32 intervenes between the cover surface 8 of the metal cover 4 and the discharge resistor 31. Specifically, the metal cover 4 has a shape forming a predetermined gap between the cover surface 8 and the discharge resistor 31 and the thermal grease 32 is applied on the discharge resistor 31. This brings the metal cover 4 into thermal contact with the discharge resistor 31 and causes the metal cover 4 to receive the heat from the discharge resistor 31.

As shown in FIG. 3, a cell voltage sensor board 7a included in the voltage detecting device 1 includes a power supply circuit 21a, an integrated circuit 30a, a direct current (DC)/DC converter 40a, and an insulating element 50a.

The power supply circuit 21a included in the cell voltage sensor board 7a generates a voltage to be supplied to a power supply of a level converter (analog conversion circuit) that employs the lowest potential of the battery cell group 12a as a reference potential Va and is included in the integrated circuit 30a. For example, the power supply circuit 21a boosts the voltage of the battery cell group 12a to generate the supply voltage of the analog conversion circuit, whose reference potential is Va.

Each of the battery cell groups 12a, 12b, and 12c is composed of plural battery cells.

The integrated circuit 30a includes the level converter 301a and an analog to digital (A/D) conversion circuit 302a.

The level converter 301a converts the cell voltage of each battery cell in the battery cell group 12a so that the maximum voltage output by the plural battery cells may become the voltage corresponding to the full scale of the A/D conversion circuit 302a. The level converter 301a operates by a power supply of a high voltage (e.g. 60 volts) for input of the voltage of the battery cell group 12a.

The cell voltage after the conversion by the level converter 301a is input to the A/D conversion circuit 302a and the A/D conversion circuit 302a generates a corresponding digital signal. The A/D conversion circuit 302a operates by a power supply (second power supply) of a low voltage (e.g. five volts).

The DC/DC converter 40a generates a voltage to be supplied to the power supply of the A/D conversion circuit (digital conversion circuit) 302a included in the integrated circuit 30a. For example, the DC/DC converter 40a generates a voltage of five volts with respect to the reference potential Va on the basis of a pulse width modulation (PWM) signal (pulse signal) generated by the processor (control unit) 80. The DC/DC converter 40a includes the first communicating element 25 and the second communicating element 26.

The insulating element 50a transmits, to the processor 80, information indicating the voltage of the battery cell converted by the integrated circuit 30a without exchange of current between the cell voltage sensor board 7a and the battery ECU board 6.

A cell voltage sensor board 7b has the same functional units as those of the cell voltage sensor board 7a except for that the reference potential is Vb. Specifically, the cell voltage sensor board 7b includes a power supply circuit 21b, an integrated circuit 30b, a DC/DC converter 40b, and an insulating element 50b.

Similarly, a cell voltage sensor board 7c has the same functional units as those of the cell voltage sensor board 7a except for that the reference potential is Vc. Specifically, the cell voltage sensor board 7c includes a power supply circuit 21c, an integrated circuit 30c, a DC/DC converter 40c, and an insulating element 50c.

The battery ECU board 6 includes the DC/DC converters 40a, 40b, 40c, . . . , the insulating elements 50a, 50b, 50c, . . . , a power supply 60, a power supply circuit 70, and the processor 80.

The power supply 60 outputs a voltage to the power supply circuit 70. For example, the power supply 60 outputs a voltage of 12 volts to the power supply circuit 70.

The power supply circuit 70 generates the supply voltage used for the operation of the processor 80 on the basis of the voltage output by the power supply 60. For example, the power supply circuit 70 generates a voltage of five volts from the voltage of 12 volts output by the power supply 60.

The processor 80 generates the PWM signal for the generation of the supply voltage of the A/D conversion circuit 302a by the DC/DC converter 40a. Furthermore, the processor 80 acquires information on the voltage of each battery cell converted by the A/D conversion circuit 302a via the insulating element 50a. The processor 80 may generate a command signal to prescribe the timing of sampling of the cell voltage of each voltage cell by the A/D conversion circuit 302a.

According to the above-described configuration, by employing wireless communications as communications between the integrated circuit 30 and the processor 80, wiring between the cell voltage sensor board 7 and the battery ECU board 6 can be omitted and thus the configuration of the voltage detecting device 1 can be further simplified.

Furthermore, even when the number of cell voltage sensor boards 7 configuring the battery B is changed, responding to the change is allowed more easily through increase or decrease in the cell voltage sensor board 7.

Furthermore, by attaching the battery ECU board 6 and the cell voltage sensor boards 7 to the locating pins 11 of the base part 9, the battery ECU board 6 and the cell voltage sensor boards 7 are disposed in parallel to each other. In addition, the first communicating element 25 and the second communicating element 26 are disposed opposed to each other. This enables wireless communications between the first communicating element 25 and the second communicating element 26, which can reduce the size of the voltage detecting device 1 as a unit having the battery ECU board 6 and the cell voltage sensor boards 7.

Moreover, by employing the configuration in which the discharge resistor 31 is mounted on the cell voltage sensor board 7 and the discharge resistor 31 is connected to the metal cover 4 by the thermal grease 32, heat generated from the cell voltage sensor board 7 is transferred not to the battery ECU board 6 but to the metal cover 4 and thus the heat resistance of the voltage detecting device 1 can be improved.

In the above embodiment, the cores 27 and the coils 28 are used as the communicating elements. However, the communicating elements are not limited thereto as long as they can be mounted on boards and enable wireless communications. For example, it is also possible to employ, as the communicating elements, antennas such as microstrip antennas (patch antennas) or communicating elements such as a light emitting element and a light receiving element.

### Second Embodiment

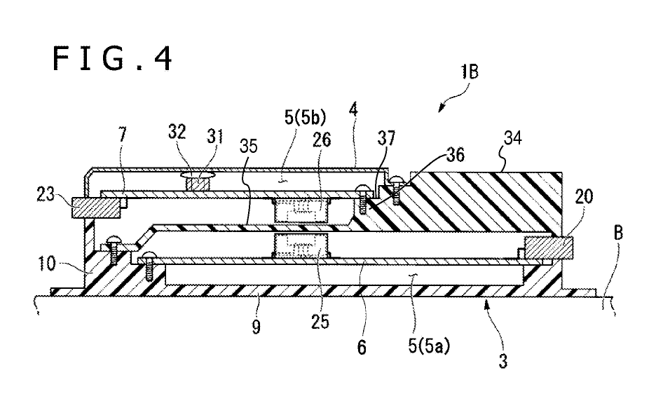

As shown in FIG. 4, a resin cover 34 intervenes between the battery ECU board 6 and the cell voltage sensor board 7 in a voltage detecting device 1B of a second embodiment of the present disclosure. The resin cover 34 is attached to the resin case 3, to which the battery ECU board 6 is attached, in such a manner as to cover the battery ECU board 6 by using fastening measures such as bolts.

The cell voltage sensor board 7 is supported by a second support surface 37 of a second support part 36 made in the resin cover 34 and the wall part 10 of the resin case 3, and at least part of the cell voltage sensor board 7 is fixed to the second support surface 37 by using fastening measures such as bolts. The second support surface 37 and the wall part 10 are so formed that the attached cell voltage sensor board 7 is disposed in parallel to the battery ECU board 6.

The resin cover 34 is so formed that the board housing space 5 is divided into a first board housing space 5a and a second board housing space 5b by attaching the resin cover 34 to the resin case 3 and then attaching the metal cover 4. The battery ECU board 6 is housed in the first board housing space 5a formed by the resin case 3 and the resin cover 34. The cell voltage sensor board 7 is housed in the second board housing space 5b formed by the resin cover 34 and the metal cover 4.

The resin cover 34 has a resin cover main body 35 that has a plate shape and is disposed in parallel to the base part 9 of the resin case 3 and the battery ECU board 6 by attaching the resin cover 34 to the resin case 3. The resin cover main body 35 is so formed that the interval between the battery ECU board 6 and the resin cover main body 35 is substantially the same as that between the cell voltage sensor board 7 and the resin cover main body 35. The thickness of the resin cover main body 35 is set as appropriate depending on the communicable distance between the communicating elements 25 and 26, the degree of heat generation of each board, the dimensions of the voltage detecting device 1B, and so forth.

Due to the formation of the resin cover 34 in this manner, the resin cover main body 35 functioning as an insulating resin is disposed between the first communicating element 25 and the second communicating element 26 of the present embodiment.

According to the above embodiment, due to the placement of the resin cover main body 35 functioning as an insulating resin between the battery ECU board 6 and the cell voltage sensor board 7, the cell voltage sensor board 7 and the battery ECU board 6 can be thermally separated from each other. By separating the cell voltage sensor board 7, on which the discharge resistor 31 configured to generate heat is mounted, from the battery ECU board 6, the temperature range in which the operation of parts such as a processor mounted on the battery ECU board 6 is ensured can be narrowed. That is, employing more inexpensive parts is allowed and cost reduction of the voltage detecting device 1B can be achieved. Furthermore, performance such as the detection accuracy can be enhanced by narrowing the temperature range in which the operation of parts such as the processor is ensured.

Although embodiments of the present disclosure are described in detail above with reference to the drawings, the respective configurations in the respective embodiments, combinations thereof, and so forth are one example and addition, omission, replacement, and other changes of the configurations can be made without departing from the gist of the present disclosure. Furthermore, the present disclosure is not limited by the embodiments and is limited only by the scope of claims.

We claim:

1. A voltage detecting device comprising:
a voltage detecting circuit that is provided for each of a plurality of battery cell groups of a battery and detects a voltage of one of the plurality of battery cell groups;
a control circuit that is insulated from the voltage detecting circuit and controls the battery on the basis of the voltage;
a control circuit board equipped with the control circuit;
a first communicating element mounted on the control circuit board;
a voltage detecting circuit board that is equipped with the voltage detecting circuit and is disposed in parallel to the control circuit board; and
a second communicating element that is mounted on the voltage detecting circuit board and is capable of contactless communication with the first communicating element;
wherein the first communicating element and the second communicating element are disposed opposed to each other.

2. The voltage detecting device according to claim 1, further comprising:
a discharge element that is mounted on the voltage detecting circuit board and discharges the one of the plurality of battery cell groups when in an overcharged state; and
an insulating resin plate disposed between the control circuit board and the voltage detecting circuit board.

3. The voltage detecting device according to claim 1, further comprising:
a discharge element that is mounted on the voltage detecting circuit board and discharges the one of the plurality of battery cell groups when in an overcharged state; and
a metal cover that is in contact with the discharge element and covers at least part of the voltage detecting circuit board.
